(19) United States
(12) Patent Application Publication
(10) Pub. No.: US 2025/0301813 A1
(43) Pub. Date: Sep. 25, 2025

(54) IMAGE SENSOR

(71) Applicant: SAMSUNG ELECTRONICS CO., LTD., Suwon-si (KR)

(72) Inventors: YONGJUN KIM, Suwon-si (KR); SEUNGSIK KIM, Suwon-si (KR); Sol YOON, Suwon-si (KR); SANG-SU PARK, Suwon-si (KR); JAEKYU LEE, Suwon-si (KR)

(73) Assignee: SAMSUNG ELECTRONICS CO., LTD., Suwon-si (KR)

(21) Appl. No.: 18/828,544

(22) Filed: Sep. 9, 2024

(30) Foreign Application Priority Data
Mar. 25, 2024 (KR) 10-2024-0040501

(51) Int. Cl. H01L 27/146

(52) U.S. Cl. CPC H10F 39/811; H10F 39/011; H10F 39/182; H10F 39/199; H10F 39/807

(57) ABSTRACT

An image sensor includes a substrate, a first floating diffusion region and a second floating diffusion region in the substrate and spaced apart from each other, a ground region in the substrate and spaced apart from the first floating diffusion region and the second floating diffusion region, a first interconnection line on the substrate and connecting the first floating diffusion region and the second floating diffusion region, and a second interconnection line on the substrate and connected to the ground region, where the first interconnection line is at a first level and the second interconnection line is at a second level that is different from the first level.

### CROSS-REFERENCE TO RELATED APPLICATIONS

This application is based on and claims priority under 35 U.S.C. § 119 to Korean Patent Application No. 10-2024-0040501, filed on Mar. 25, 2024, in the Korean Intellectual Property Office, the disclosure of which is incorporated by reference herein in its entirety.

### BACKGROUND

Example embodiments of the disclosure relate to an image sensor.

An image sensor may refer to a semiconductor device converting an optical image to electric signals. The image sensor may be classified into two types: a charge coupled device (CCD) type and a complementary metal-oxide-semiconductor (CMOS) type. In general, the CMOS-type image sensor (CIS) may include a plurality of pixels that are two-dimensionally arranged. Each of the pixels may include a photodiode. The photodiode may be used to convert an incident light to an electric signal.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an image sensor that may be capable of reducing a signal noise.

Additional aspects will be set forth in part in the description which follows and, in part, will be apparent from the description, or may be learned by practice of the presented embodiments.

According to an aspect of an example embodiment, an image sensor may include a substrate, a first floating diffusion region and a second floating diffusion region in the substrate and spaced apart from each other, a ground region in the substrate and spaced apart from the first floating diffusion region and the second floating diffusion region, a first interconnection line on the substrate and connecting the first floating diffusion region and the second floating diffusion region, and a second interconnection line on the substrate and connected to the ground region, where the first interconnection line is at a first level and the second interconnection line is at a second level that is different from the first level.

According to an aspect of an example embodiment, an image sensor may include a first floating diffusion region, a ground region spaced apart from the first floating diffusion region, a source follower gate electrode spaced apart from the first floating diffusion region, a first interlayer insulating layer on the source follower gate electrode, a first interconnection line on the first interlayer insulating layer and connecting the first floating diffusion region to the source follower gate electrode, a second interlayer insulating layer on the first interconnection line and the first interlayer insulating layer, and a second interconnection line on the second interlayer insulating layer and connected to the ground region, where the first interconnection line has a first thickness, and the second interconnection line has a second thickness that is larger than the first thickness.

According to an aspect of an example embodiment, an image sensor may include a substrate including a pixel array region, an optical black region, and a pad region, the pixel array region including a first pixel group and a second pixel group adjacent to each other in a first direction, the first pixel group and the second pixel group including pixels that are arranged in a 2×2 matrix, a pixel isolation portion in the substrate and separating the first pixel group and the second pixel group, a first floating diffusion region at a center of the first pixel group, a second floating diffusion region at a center of the second pixel group, a ground region in the substrate and in one of the pixels of the first pixel group, a first transfer gate electrode adjacent to the first floating diffusion region, a second transfer gate electrode adjacent to the second floating diffusion region, a first interlayer insulating layer at least partially covering the substrate, the first floating diffusion region, the second floating diffusion region, the ground region, the first transfer gate electrode and the second transfer gate electrode, a first interconnection line on the first interlayer insulating layer and connecting the first floating diffusion region to the second floating diffusion region, a second interlayer insulating layer at least partially covering the first interconnection line and the first interlayer insulating layer, a second interconnection line on the second interlayer insulating layer and connected to the ground region, a light-blocking pattern on the second interlayer insulating layer and in the optical black region, a conductive pad on the second interlayer insulating layer and in the pad region, a first contact plug penetrating the first interlayer insulating layer and connecting the first interconnection line to the first floating diffusion region, and a second contact plug penetrating the first interlayer insulating layer and the second interlayer insulating layer, the second contact plug connecting the second interconnection line to the ground region, where the first contact plug includes polysilicon doped with impurities of a first conductivity type, and the second contact plug includes a metallic material.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a plan view illustrating an image sensor according to one or more embodiments;

FIG. 2 is a plan view illustrating the image sensor of FIG. 1, in which interconnection lines are added according to one or more embodiments;

FIG. 3 is a perspective view illustrating a portion of the image sensor of FIG. 2 according to one or more embodiments;

FIG. 4 is a circuit diagram illustrating the image sensor of FIG. 2 according to one or more embodiments;

FIG. 5 is a cross-sectional view taken along a line A-A′ of FIG. 2 according to one or more embodiments;

FIG. 6 is an enlarged sectional view illustrating a portion ‘P1’ of FIG. 5 according to one or more embodiments;

FIG. 7A is a cross-sectional view of an example taken along the line A-A′ of FIG. 2 according to one or more embodiments;

FIG. 7B is a cross-sectional view of an example taken along the line A-A′ of FIG. 2 according to one or more embodiments;

FIGS. 8A to 8I are diagrams illustrating a fabrication process according to one or more embodiments;

FIG. 9 is a cross-sectional view illustrating an image sensor according to one or more embodiments;

FIG. 10A is a cross-sectional view illustrating an image sensor according to one or more embodiments; and

FIG. 10B is a cross-sectional view illustrating an image sensor according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

It will be understood that, although the terms “first”, “second”, etc. may be used herein to describe various elements, components, regions, layers and/or sections, these elements, components, regions, layers and/or sections should not be limited by these terms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

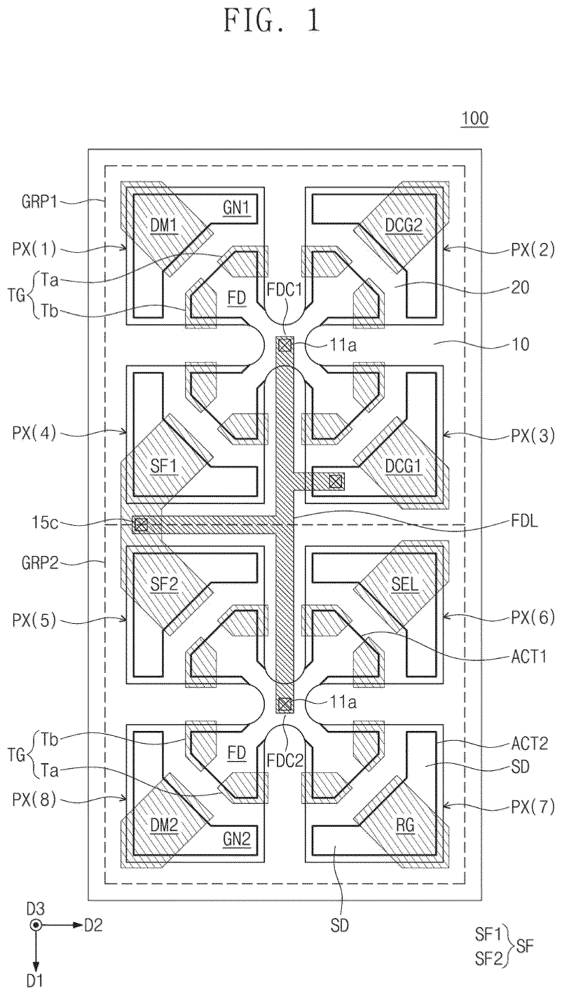

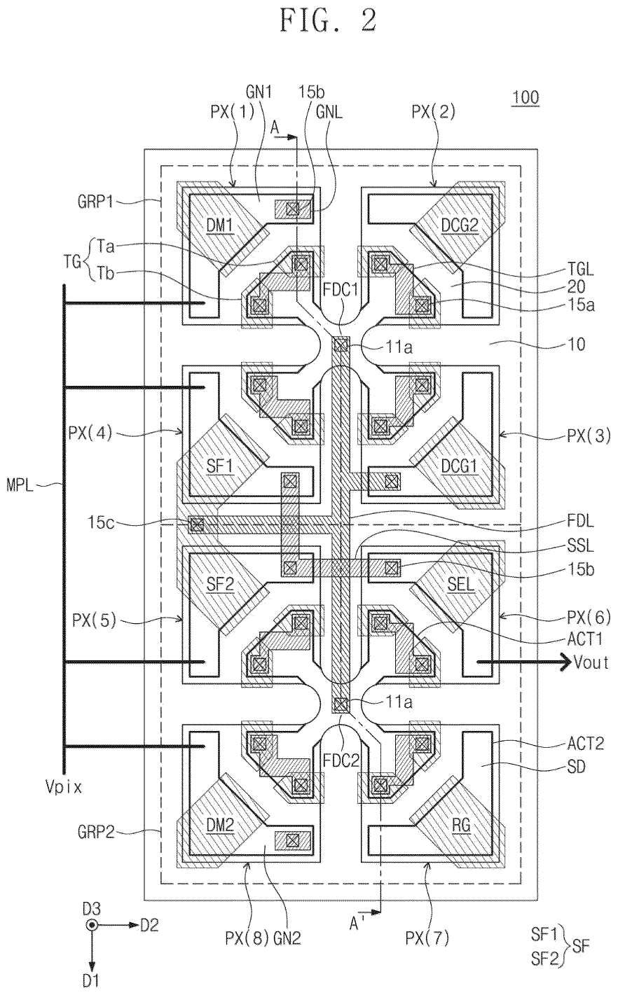

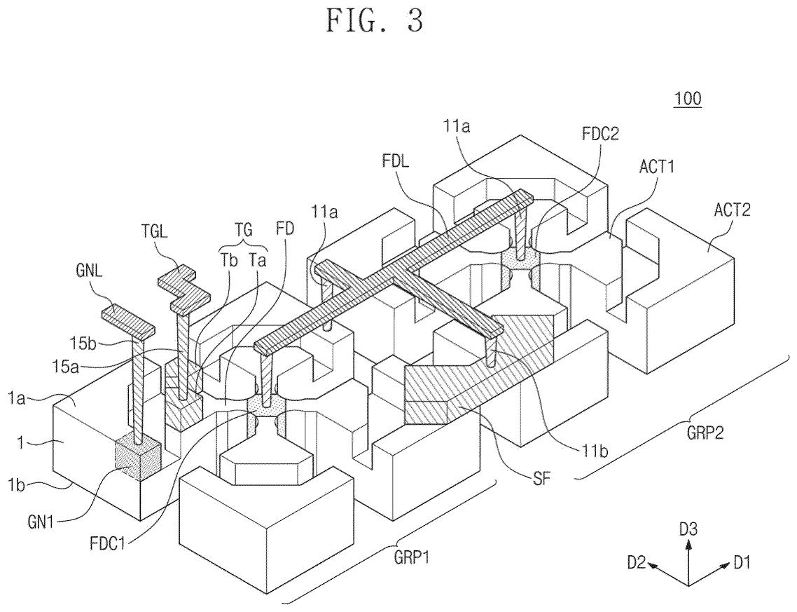

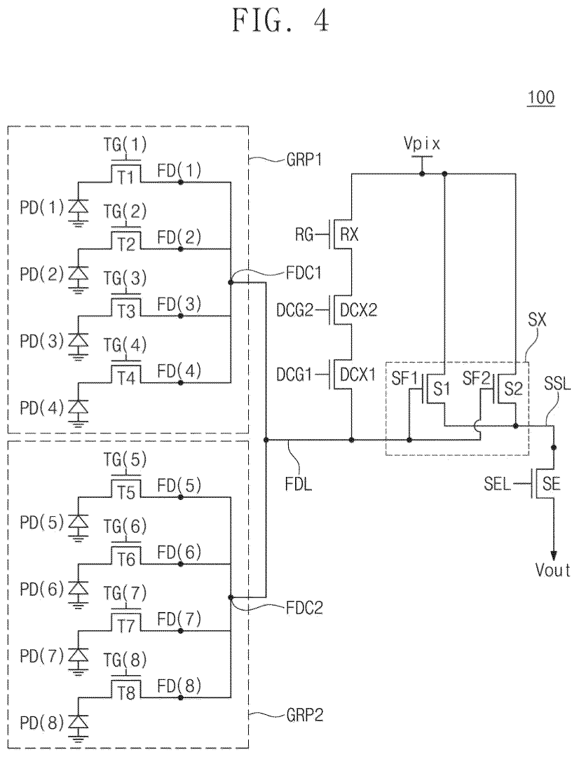

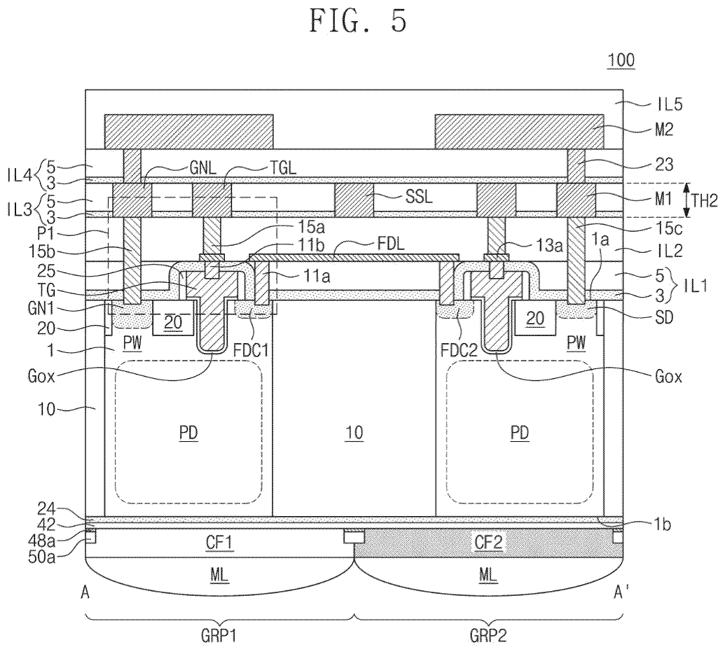

FIG. 1 is a plan view illustrating an image sensor according to one or more embodiments. FIG. 2 is a plan view illustrating the image sensor of FIG. 1, in which interconnection lines are added, according to one or more embodiments. FIG. 3 is a perspective view illustrating a portion of the image sensor of FIG. 2 according to one or more embodiments. FIG. 4 is a circuit diagram of the image sensor of FIG. 2 according to one or more embodiments. FIG. 5 is a cross-sectional view taken along a line A-A′ of FIG. 2 according to one or more embodiments.

Referring to FIGS. 1 to 5, an image sensor 100 may include a substrate 1. The substrate 1 may include a plurality of pixels PX, which are two-dimensionally arranged in two different directions (e.g., a first direction D1 and a second direction D2). The substrate 1 may include a first surface 1a and a second surface 1b, which are opposite to each other. Light may be incident into the substrate 1 through the second surface 1b. The substrate 1 may be a single crystalline wafer, which is formed of or includes silicon and/or germanium, an epitaxial layer, or a silicon-on-insulator (SOI) wafer. A well region PW may be formed in the substrate 1. The well region PW may be doped with impurities of a first conductivity type. The first conductivity type may be, for example, a p-type. The impurities of the first conductivity type may be, for example, boron.

A pixel isolation portion 10 may be disposed in the substrate 1 to separate and isolate the pixels PX from each other. The pixel isolation portion 10 may have a mesh or net shape, in a plan view. The pixel isolation portion 10 may include an isolation conductive pattern, which is provided therein, and an isolation insulating pattern, which is provided between the isolation conductive pattern and the substrate 1. The pixel isolation portion 10 may be provided to penetrate the substrate 1.

In one or more embodiments, the pixels PX, which may be arranged in a 2×2 matrix, may constitute one pixel group GRP1 or GRP2. In one or more embodiments, a plurality of pixel groups GRP1 and GRP2 may be provided and may be arranged in the first and second directions D1 and D2. Referring to FIGS. 1 and 2, the pixel groups GRP1 and GRP2 may include a first pixel group GRP1 and a second pixel group GRP2. The first pixel group GRP1 may include first to fourth pixels PX(1)-PX(4). The second pixel group GRP2 may include fifth to eighth pixels PX(5)-PX(8). The pixel isolation portion 10 may separate the pixel groups GRP1 and GRP2 from each other. In each of the pixel groups GRP1 and GRP2, the pixel isolation portion 10 may separate the pixels PX from each other. The pixel isolation portion 10 may not extend into the center of each of the pixel groups GRP1 and GRP2.

In each of the pixels PX, a photoelectric conversion component PD may be disposed in the substrate 1. The photoelectric conversion component PD may be doped with impurities, which are of a second conductivity type different from the first conductivity type. In one or more embodiments, the second conductivity type may be an n-type. The impurities of the second conductivity type may be, for example, phosphorus or arsenic. The photoelectric conversion component PD and the well region PW, which are the n-and p-type impurity regions, respectively, may form a P-N junction that may be used as a photodiode. In the case where light is incident into the P-N junction, electron-hole pairs may be generated in the P-N junction. The electrons may be transferred and stored in the photoelectric conversion component PD, which is the n-type impurity region.

In each of the pixels PX, a device isolation portion 20 may be disposed in a portion of the substrate 1 near the first surface 1a to define first and second active regions ACT1 and ACT2. The device isolation portion 20 may be formed by a shallow trench isolation (STI) method. The device isolation portion 20 may be formed of or include at least one of silicon oxide, silicon nitride, and silicon oxynitride and may have a single-layered or multi-layered structure. Alternatively, the device isolation portion 20 may be formed by doping a high concentration of impurities, which are of the same conductivity type (i.e., the first conductivity type) as the substrate 1, into the substrate 1. The pixel isolation portion 10 may be provided to penetrate the device isolation portion 20. The device isolation portion 20 may not extend into the center region of each of the pixel groups GRP1 and GRP2.

Transfer transistors T1-T8 may be disposed to correspond to the first active regions ACT1 of the first to eighth pixels PX(1) to PX(8). In each of the pixels PX, an end of one of the transfer transistors T1-T8 may be connected to the photoelectric conversion component PD. Each of the transfer transistors T1-T8 may include a floating diffusion region FD, which may be formed in the substrate 1, and a transfer gate electrode TG, which may be disposed near the floating diffusion region FD. Each transfer gate electrode TG may include a first sub-transfer gate Ta and a second sub-transfer gate Tb, which may be separated from each other. The floating diffusion region FD may be doped with impurities of the second conductivity type.

In the center region of the first pixel group GRP1, the floating diffusion regions FD of the first to fourth pixels PX(1)-PX(4) may be connected to each other to form a first common floating diffusion region FDC1. In the center region of the second pixel group GRP2, the floating diffusion regions FD of the fifth to eighth pixels PX(5) to PX(8) may be connected to each other to form a second common floating diffusion region FDC2. The first and second common floating diffusion regions FDC1 and FDC2 may be doped to have the same conductivity type (i.e., the second conductivity type) and impurity concentration as the floating diffusion regions FD. Reference to a floating diffusion region may include the floating diffusion regions FD as well as the common floating diffusion regions FDC1 and FDC2. That is, the term “floating diffusion region” may refer to an individual common floating diffusion region (e.g., FDC1) and the corresponding floating diffusion regions FD of the corresponding pixels. The floating diffusion regions FD may be continuous with the common floating diffusion regions FDC1 and FDC2, such that no explicit boundary may be provided between the floating diffusion regions FD and the common floating diffusion regions FDC1 and FDC2.

The gate electrode of the driving transistor or the gate electrode of the dummy transistor may be disposed in each of the second active regions ACT2 of the first to eighth pixels PX(1) to PX(8). Each of the second active regions ACT2 may have an ‘L’-shaped region, in a plan view.

Referring to FIG. 1, a first dummy gate electrode DM1 may be disposed on the center region of the second active region ACT2 of the first pixel PX(1) of the first pixel group GRP1. A first ground region GN1 may be disposed in a portion of the substrate 1 at a side of the first dummy gate electrode DM1. The first ground region GN1 may be doped with impurities of the first conductivity type, and the doping concentration of the first ground region GN1 may be higher than that in the well region PW of the substrate 1. The first ground region GN1 may contact the well region PW of the first pixel group GRP1. A source/drain region SD may be disposed in a portion of the substrate 1 at an opposite side of the first dummy gate electrode DM1, and the source/drain region SD may be doped with impurities of the second conductivity type.

A second double conversion gate electrode DCG2 may be disposed in the center region of the second active region ACT2 of the second pixel PX(2) of the first pixel group GRP1. The source/drain regions SD, which may be doped with impurities of the second conductivity type, may be disposed in portions of the substrate 1 at both sides of the second double conversion gate electrode DCG2, and in this case, the source/drain regions SD and the second double conversion gate electrode DCG2 may constitute a second double conversion transistor DCX2 of FIG. 4.

A first double conversion gate electrode DCG1 may be disposed in the center region of the second active region ACT2 of the third pixel PX(3) of the first pixel group GRP1. The source/drain regions SD, which may be doped with impurities of the second conductivity type, may be disposed in portions of the substrate 1 at both sides of the first double conversion gate electrode DCG1, and in this case, the source/drain regions SD and the first double conversion gate electrode DCG1 may constitute a first double conversion transistor DCX1 of FIG. 4.

A first source follower gate electrode SF1 may be disposed in the center region of the second active region ACT2 of the fourth pixel PX(4) of the first pixel group GRP1. The source/drain regions SD, which may be doped with impurities of the second conductivity type, may be disposed in portions of the substrate 1 at both sides of the first source follower gate electrode SF1, and in this case, the source/drain regions SD and the first source follower gate electrode SF1 may constitute a first source follower transistor S1 of FIG. 4.

The fifth pixel PX(5) of the second pixel group GRP2 may be adjacent to the fourth pixel PX(4) of the first pixel group GRP1 in the first direction D1. A second source follower gate electrode SF2 may be disposed in the center region of the second active region ACT2 of the fifth pixel PX(5) of the second pixel group GRP2. The source/drain regions SD, which may be doped with impurities of the second conductivity type, may be disposed in portions of the substrate 1 at both sides of the second source follower gate electrode SF2, and in this case, the source/drain regions SD and the second source follower gate electrode SF2 may constitute a second source follower transistor S2 of FIG. 4. In one or more embodiments, the first and second source follower gate electrodes SF1 and SF2 may be connected to each other to form a single object serving as a source follower gate electrode SF. For example, the source follower gate electrode SF may be disposed to cross the pixel isolation portion 10 between the first and second pixel groups GRP1 and GRP2.

A selection gate electrode SEL may be disposed in the center region of the second active region ACT2 of the sixth pixel PX(6) of the second pixel group GRP2. The source/drain regions SD, which may be doped with impurities of the second conductivity type, may be disposed in portions of the substrate 1 at both sides of the selection gate electrode SEL, and in this case, the source/drain regions SD and the selection gate electrode SEL may constitute a selection transistor SE of FIG. 4.

A reset gate electrode RG may be disposed in the center region of the second active region ACT2 of the seventh pixel PX(7) of the second pixel group GRP2. The source/drain regions SD, which may be doped with impurities of the second conductivity type, may be disposed in portions of the substrate 1 at both sides of the reset gate electrode RG, and in this case, the source/drain regions SD and the reset gate electrode RG may constitute a reset transistor RX of FIG. 4.

A second dummy gate electrode DM2 may be disposed in the center region of the second active region ACT2 of the eighth pixel PX (8) of the second pixel group GRP2. A second ground region GN2 may be disposed in a portion of the substrate 1 at a side of the second dummy gate electrode DM2. The second ground region GN2 may be doped with impurities of the first conductivity type, and the doping concentration of the first ground region GN1 may be higher than that in the well region PW of the substrate 1. The second ground region GN2 may contact the well region PW of the second pixel group GRP2. The source/drain region SD may be disposed in a portion of the substrate 1 at an opposite side of the second dummy gate electrode DM2.

Referring to FIG. 1, an FD connection line FDL may be provided to connect the first common floating diffusion region FDC1, the second common floating diffusion region FDC2, and the source follower gate electrode SF to each other. The FD connection line FDL may be connected to the source/drain region SD that is near the first double conversion gate electrode DCG1. The FD connection line FDL may be referred to as a first interconnection line.

Referring to FIGS. 2 and 3, a transfer gate connection line TGL may connect the first sub-transfer gate Ta and the second sub-transfer gate Tb, which are adjacent to each other on one first active region ACT1, to each other. The first ground region GN1 and the second ground region GN2 may be connected to a ground line GNL. The transfer gate connection line TGL and the ground line GNL may be located at a level higher than the FD connection line FDL. The transfer gate connection line TGL and the ground line GNL may be provided to have thicknesses that are larger than a thickness of the FD connection line FDL. The transfer gate connection line TGL may be referred to as a second interconnection line.

Referring to FIG. 2, the source/drain regions SD, which are at one side of the first dummy gate electrode DM1, the first source follower gate electrode SF1, the second source follower gate electrode SF2, and the second dummy gate electrode DM2, may be connected to a pixel voltage line MPL. The source/drain regions SD, which are at an opposite side of the first and second source follower gate electrodes SF1 and SF2, and the source/drain region SD, which is at one side of the selection gate electrode SEL, may be connected to an SF-SEL connection line SSL. The SF-SEL connection line SSL may have a shape of letter ‘L’, in a plan view. The source/drain region SD, which is at an opposite side of the selection gate electrode SEL, may be connected to an output line Vout. The interconnection structure between other transistors may be the same or similar to that shown in FIG. 4. The SF-SEL connection line SSL may be referred to as a third interconnection line.

Referring to FIGS. 1 to 4, in the image sensor 100 according to one or more embodiments, the first to eighth pixels PX(1) to PX(8), which are disposed in the first and second pixel groups GRP1 and GRP2, may be configured to share the first and second source follower transistors S1 and S2, the reset transistor RX, the first and second double conversion transistors DCX1 and DCX2, and the selection transistor SE.

In the case where one of the transfer transistors T1-T8 in one of the pixels PX is turned on, the electrons, which are accumulated in the photoelectric conversion component PD, may be transferred to the floating diffusion region FD. This may lead to a change in voltage level of the floating diffusion region FD. The reset transistor RX may be used to reset the floating diffusion region FD. For example, when the first and second double conversion transistors DCX1 and DCX2 are turned on, by applying an electric signal (e.g., a reset signal) to the reset gate electrode RG, the floating diffusion region FD may be electrically connected to a power voltage Vpix through the reset transistor RX. In this case, the voltage level of the floating diffusion region FD may be initialized by the power voltage Vpix. That is, the electrons stored in the floating diffusion region FD may be discharged to a node, to which the power voltage Vpix is applied, through the reset transistor RX applied with the reset signal.

The first and second source follower transistors S1 and S2 may be connected in parallel to form a finger-type source follower transistor SX. The source follower transistor SX may have the source follower gate electrode SF, to which the first and second source follower gate electrodes SF1 and SF2 are connected in common. The source follower gate electrode SF may be connected to the floating diffusion region FD.

The source follower transistor SX may be between and connected to the power voltage Vpix and the selection transistor SE. A voltage level in one terminal of the source follower transistor SX may be changed depending on the voltage level of the floating diffusion region FD, and if the selection transistor SE is turned on, an output signal of the selection transistor SE may be transmitted to the output line Vout.

The source follower transistor SX may be extremely sensitive to its own thermal and flicker noises, compared with other transistors (e.g., the transfer transistor, the reset transistor, and the selection transistor). A noise signal in the source follower transistor SX may be directly transmitted to an internal circuit of the image sensor, and thus, it may deteriorate the quality of images produced by the image sensor. However, in the case where the finger-type source follower transistor SX is provided, the influence of the thermal and flicker noises, which are produced in the transistor, on the image quality of the image sensor may be reduced, and an electric potential of the floating diffusion region FD may be effectively sensed. Furthermore, a current amount of the source follower transistor SX may be increased. In this case, the source follower transistor SX may exhibit better linearity in a voltage-current graph, and noise signals (e.g., random noise signals and random telegraphy signals) may be reduced.

The first and second double conversion transistors DCX1 and DCX2 may be between and connected to the floating diffusion region FD and the reset transistor RX. If the first and second double conversion transistors DCX1 and DCX2 are turned off, the full well capacity (FWC) of the pixel PX may be given by a capacitance of the floating diffusion region FD. If at least one of the first and second double conversion transistors DCX1 and DCX2 is turned on, the FWC of the pixel PX may be increased to a value greater than the capacitance of the floating diffusion region FD. In a low brightness mode, both of the first and second double conversion transistors DCX1 and DCX2 may be turned off. In a middle brightness mode, the first double conversion transistor DCX1 may be turned on, and the second double conversion transistor DCX2 may be turned off. In a high brightness mod, both the first and second double conversion transistors DCX1 and DCX2 may be turned on. That is, by turning the first and second double conversion transistors DCX1 and DCX2 on and off depending on the brightness mode, a conversion gain of the pixel PX may be adjusted. Accordingly, a high-quality image with an improved high dynamic range (HDR) property may be realized.

When the image sensor 100 is in a full mode, a turn-on voltage may be sequentially applied to the first to eighth transfer gate electrodes TG(1) to TG(8) to output signals from respective pixels PX. In a binning mode, the turn-on voltage may be simultaneously applied to all the transfer gate electrodes TG in each pixel group, allowing signals to be output for each pixel group.

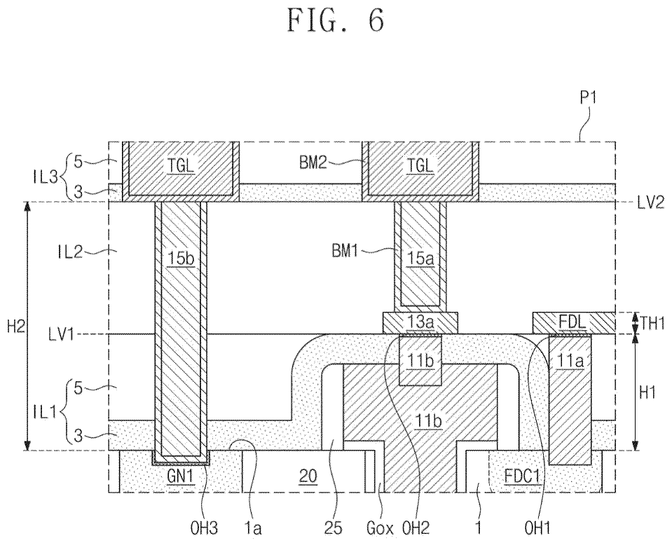

FIG. 6 is an enlarged cross-sectional view illustrating a portion ‘P1’ of FIG. 5 according to one or more embodiments.

Referring to FIGS. 5 and 6, a gate insulating layer Gox may be interposed between the transfer gate electrode TG and the substrate 1. In the other driving transistors or the dummy transistors, the gate insulating layer Gox may also be interposed between the gate electrodes RG, DCG1, DCG2, SF1, SF2, SEL, DM1, and DM2 and the substrate 1. The gate insulating layer Gox may be formed of or include at least one of silicon oxide, silicon nitride, silicon oxynitride, and metal oxide materials and may be provided to have a single-layered or multi-layered structure. The transfer gate electrode TG and the gate electrodes RG, DCG1, DCG2, SF1, SF2, SEL, DM1, and DM2 may be formed of or include at least one of doped polysilicon and metallic materials (e.g., tungsten and aluminum). In one or more embodiments, the transfer gate electrode TG and the gate electrodes RG, DCG1, DCG2, SF1, SF2, SEL, DM1, and DM2 may be formed of doped polysilicon.

In each of the pixels PX, the photoelectric conversion component PD, which is disposed in the substrate 1, may be overlapped with one transfer gate electrode TG and one of the gate electrodes RG, DCG1, DCG2, SF1, SF2, SEL, DM1, and DM2. A side surface of the transfer gate electrode TG may be covered with a spacer 25. The spacer 25 may be formed of or include at least one of silicon oxide, silicon nitride, and silicon oxynitride and may be provided to have a single-layered or multi-layered structure.

The first surface 1a of the substrate 1 and the gate electrodes TG, RG, DCG1, DCG2, SF1, SF2, SEL, DM1, and DM2 may be covered with a first interlayer insulating layer IL1. The first interlayer insulating layer IL1 may include an etch stop layer 3 and a planarization layer 5. The etch stop layer 3 may be formed conformally. The planarization layer 5 may fill a space between the gate electrodes TG, RG, DCG1, DCG2, SF1, SF2, SEL, DM1, and DM2. On the gate electrodes TG, RG, DCG1, DCG2, SF1, SF2, SEL, DM1, and DM2, a top surface of the planarization layer 5 may be coplanar with a top surface of the etch stop layer 3. The etch stop layer 3 may have an etch selectivity with respect to the planarization layer 5. In one or more embodiments, the etch stop layer 3 may be formed of or include at least one of SiN, SiCN, and SiON. For example, the planarization layer 5 may be formed of or include at least one of silicon oxide and porous insulating materials.

First contact plugs 11a and 11b may be provided to penetrate the first interlayer insulating layer IL1. The first contact plugs 11a and 11b may include an FD connection contact plug 11a and first gate contact plugs 11b. The FD connection contact plug 11a may be provided to penetrate the first interlayer insulating layer IL1 and may contact the first common floating diffusion region FDC1 and the second common floating diffusion region FDC2. The first gate contact plugs 11b may be provided to penetrate the etch stop layer 3 of the first interlayer insulating layer IL1 and contact the gate electrodes TG, RG, DCG1, DCG2, SF1, SF2, SEL, DM1, and DM2. The first contact plugs 11a and 11b may be formed of or include doped polysilicon. For example, the FD connection contact plug 11a may be formed of or include polysilicon that is doped to have the same conductivity type (e.g., the second conductivity type) as the floating diffusion regions FD, the first common floating diffusion region FDC1, and the second common floating diffusion region FDC2. Thus, a junction leakage between the FD connection contact plugs 11a and the first and second common floating diffusion regions FDC1 and FDC2 may be prevented and reduced, compared to the case where the FD connection contact plugs 11a include a metallic material.

The FD connection line FDL and gate conductive pads 13a may be disposed on the first interlayer insulating layer IL1. The FD connection line FDL and the gate conductive pads 13a may have the same material and thickness as each other. For example, the FD connection line FDL and the gate conductive pads 13a may be formed of or include at least one of titanium and titanium nitride and may have a single-layered or multi-layered structure. The FD connection line FDL may cover top portions of the FD connection contact plugs 11a. A first ohmic layer OHI may be interposed between the FD connection line FDL and the FD connection contact plugs 11a. The FD connection line FDL may overlap the FD connection contact plugs 11a, the source follower gate electrode SF, and the source/drain region SD near the first double conversion gate electrode DCG1. The gate conductive pads 13a may cover top portions of the first gate contact plugs 11b, respectively. A second ohmic layer OH2 may be interposed between the gate conductive pads 13a and the first gate contact plugs 11b. The first ohmic layer OHI and the second ohmic layer OH2 may be formed of or include TiSi or TiSiN.

A second interlayer insulating layer IL2 may be disposed on the first interlayer insulating layer IL1. The second interlayer insulating layer IL2 may be formed of or include at least one of silicon oxide, silicon nitride, silicon oxynitride, and porous insulating materials and may have a single-layered or multi-layered structure. Second contact plugs 15a, 15b, and 15c may be provided to penetrate the second interlayer insulating layer IL2. Each of the second contact plugs 15a, 15b, and 15c may be formed of or include a metallic material (e.g., tungsten). Side and bottom surfaces of each of the second contact plugs 15a, 15b, and 15c may be covered with a first diffusion barrier layer BM1. In one or more embodiments, the first diffusion barrier layer BM1 may be formed of Ti/TiN.

The second contact plugs 15a, 15b, and 15c may include the second gate contact plugs 15a and the first and second substrate connection contact plug 15b and 15c. The second gate contact plugs 15a may be provided to penetrate the second interlayer insulating layer IL2 and may be connected to the gate conductive pads 13a. The first substrate connection contact plugs 15b may be provided to penetrate the second interlayer insulating layer IL2 and the first interlayer insulating layer IL1 and may be connected to the ground regions GN1 and GN2. The second substrate connection contact plugs 15c may be provided to penetrate the second interlayer insulating layer IL2 and the first interlayer insulating layer IL1 and may be connected to the source/drain regions SD. A third ohmic layer OH3 may be interposed between the first and second substrate connection contact plug 15b and 15c and the substrate 1. The third ohmic layer OH3 may be formed of or include TiSi or TiSiN.

The FD connection contact plugs 11a may have a first height H1, from the first surface 1a of the substrate 1. The first and second substrate connection contact plug 15b and 15c may have a second height H2, from the first surface 1a of the substrate 1. The second height H2 may be larger than the first height H1.

Third to fifth interlayer insulating layers IL3, IL4, and IL5 may be sequentially formed on the second interlayer insulating layer IL2. At least one of the third to fifth interlayer insulating layers IL3, IL4, and IL5 may include the etch stop layer 3 and the planarization layer 5, which may be sequentially stacked. The ground line GNL, the transfer gate connection line TGL, the SF-SEL connection line SSL, and the first interconnection lines M1 may be disposed in the third interlayer insulating layer IL3. A third contact plug 17 may be provided to penetrate the fourth interlayer insulating layer IL4 and may be connected to at least one of the first interconnection lines M1 and the ground line GNL. Second interconnection lines M2 may be disposed on the fourth interlayer insulating layer IL4.

Each of the ground line GNL, the transfer gate connection line TGL, the SF-SEL connection line SSL, the first interconnection lines M1, the third contact plug 17, and the second interconnection lines M2 may be formed of or include a metallic material that is different from the FD connection line FDL and the gate conductive pads 13a. An electrical resistivity of each of the ground line GNL, the transfer gate connection line TGL, the SF-SEL connection line SSL, the first interconnection lines M1, the third contact plug 17, and the second interconnection lines M2 may be smaller than an electrical resistivity of each of the FD connection line FDL and the gate conductive pads 13a. For example, each of the FD connection line FDL and the gate conductive pads 13a may be formed of a material having an electrical resistivity of 22-54 μΩ·cm. Each of the ground line GNL, the transfer gate connection line TGL, the SF-SEL connection line SSL, the first interconnection lines M1, the third contact plug 17, and the second interconnection lines M2 may be formed of a material having an electrical resistivity of 1-5 μΩ·cm. For example, each of the ground line GNL, the transfer gate connection line TGL, the SF-SEL connection line SSL, the first interconnection lines M1, the third contact plug 17, and the second interconnection lines M2 may be formed of or include copper. This difference in the electrical resistivity may result in a reduction of a parasitic capacitance between the FD connection line FDL and other interconnection lines (e.g., TGL, SSL, and M1) adjacent thereto. As a result, it a noise signal may be reduced and thereby a high-quality image may be realized.

Each of the FD connection line FDL and the gate conductive pads 13a may have a first thickness TH1, as shown in FIG. 6. Each of the ground line GNL, the transfer gate connection line TGL, the SF-SEL connection line SSL, the first interconnection lines M1, the third contact plug 17, and the second interconnection lines M2 may have a second thickness TH2, as shown in FIG. 5. The second thickness TH2 may be larger than the first thickness TH1. For example, the second thickness TH2 may be 10 to 100 times the first thickness TH1.

The side and bottom surfaces of each of the ground line GNL, the transfer gate connection line TGL, the SF-SEL connection line SSL, the first interconnection lines M1, the third contact plug 17, and the second interconnection lines M2 may be covered with a second diffusion barrier layer BM2. The second diffusion barrier layer BM2 may include a material different from the first diffusion barrier layer BM1. For example, the second diffusion barrier layer BM2 may be formed of or include Ta/TaN.

In one or more embodiments, the FD connection line FDL may be located at a first level LV1. The ground line GNL, the transfer gate connection line TGL, the SF-SEL connection line SSL, and the first interconnection lines M1 may be located at a second level LV2. The second level LV2 may be different from the first level LV1. For example, the first level LV1 may be lower than the second level LV2. In other words, the FD connection line FDL may be located at a level lower than the transfer gate connection line TGL, the SF-SEL connection line SSL, and the first interconnection lines M1. In this case, distances between the FD connection line FDL and other interconnection lines TGL, SSL, and M1 may be increased, and consequently, a parasitic capacitance therebetween may be reduced. As a result, a noise signal may be reduced and thereby a high-quality image may be realized. In addition, the transfer gate connection line TGL, the SF-SEL connection line SSL, and the first interconnection lines M1 may be provided/positioned, without considering the position and shape of the FD connection line FDL. That is, a degree of freedom in designing an interconnection structure may be increased.

A fixed charge layer 24 may be disposed under the second surface 1b of the substrate 1. The fixed charge layer 24 may contact the second surface 1b. The fixed charge layer 24 may be formed of a metal oxide layer, whose oxygen content is lower than its stoichiometric ratio, or a metal fluoride layer, whose fluorine content ratio is lower than its stoichiometric ratio. Thus, the fixed charge layer 24 may have negative fixed charges. The fixed charge layer 24 may be formed of metal oxide or metal fluoride containing at least one metal, of hafnium (Hf), zirconium (Zr), aluminum (Al), tantalum (Ta), titanium (Ti), yttrium (Y), and lanthanoid. The hole accumulation may occur near the fixed charge layer 24. In this case, the dark current issue and the white spot issue may be effectively suppressed. In one or more embodiments, the fixed charge layer 24 may be at least one of an aluminum oxide layer or a hafnium oxide layer.

An anti-reflection layer 42 may be disposed below the fixed charge layer 24. The anti-reflection layer 42 may be formed of or include, for example, silicon nitride. A first grid pattern 48a and a second grid pattern 50a may be sequentially stacked on the anti-reflection layer 42. The first grid pattern 48a and the second grid pattern 50a may be provided to have a mesh or net shape, when viewed in a plan view. The first grid pattern 48a and the second grid pattern 50a may be provided to expose the anti-reflection layer 42.

A side surface of the second grid pattern 50a may be aligned to a side surface of the first grid pattern 48a. The first grid pattern 48a and the second grid pattern 50a may prevent a cross-talk issue from occurring between adjacent ones of the pixels. The first grid pattern 48a may be formed of or include an opaque material (e.g., titanium or tungsten). The second grid pattern 50a may be formed of or include an organic material. The second grid pattern 50a may have a refractive index that is lower smaller than color filters CF1 and CF2. For example, the second grid pattern 50a may have a refractive index of about 1.3 or lower.

The color filters CF1 and CF2 may be disposed on the anti-reflection layer 42. The colors of the color filters CF1 and CF2 may be determined depending on whether they are included in the pixel group GRP1 or GRP2. For example, a first color filter CF1 may be disposed below the first pixel group GRP1. The first to fourth pixels PX(1)-PX(4) of the first pixel group GRP1 may be covered with the first color filter CF1 of the same color. A second color filter CF2 may be disposed below the second pixel group GRP2. The fifth to eighth pixels PX(5)-PX(8) of the second pixel group GRP2 may be covered with the second color filter CF2 of the same color.

The color filters CF1 and CF2 may include a photoresist material containing a dye or pigment. The color filters CF1 and CF2 may be two-dimensionally arranged in the first and second directions D1 and D2 to form a color filter array. The color filter array may be provided to form an RGB pattern of red (R), green (G), and blue (B) or to form an RGBW pattern further including a white pixel. The white pixel may be a pixel that is configured to sense light within the entire or visible wavelength range. In one or more embodiments, there may be no color filter on the white pixel, and in this case, a portion of a micro lens ML may be provided in place of the color filter. In one or more embodiments, the color filter array may be provided to form a complementary color pattern of cyan, yellow, and magenta. The color filter array may be provided in the form of a Bayer pattern, a 2×2 tetra pattern, a 3×3 Nona pattern, or a 4×4 hexadeca pattern.

The micro lenses ML may be disposed below the color filters CF1 and CF2. End portions of the micro lenses ML may contact, and may be connected to, each other. The first pixel group GRP1 may be covered with one micro lens ML. The second pixel group GRP2 may be covered with another micro lens ML. Signals, which are output from the pixels PX at different positions in one of the pixel groups GRP1 and GRP2, may be used to realize an auto-focusing function of the image sensor 100 (e.g., using a difference in phase between the output signals).

The image sensor 100 may also be operated in a global shutter mode. For this, the image sensor 100 may further include a precharge transistor, a sampling transistor, and/or a capacitor, which is connected to the output line Vout.

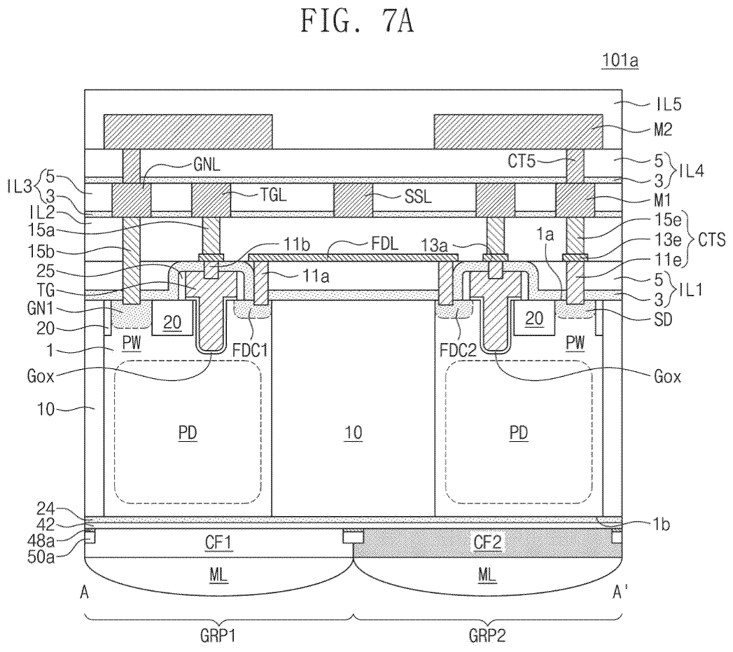

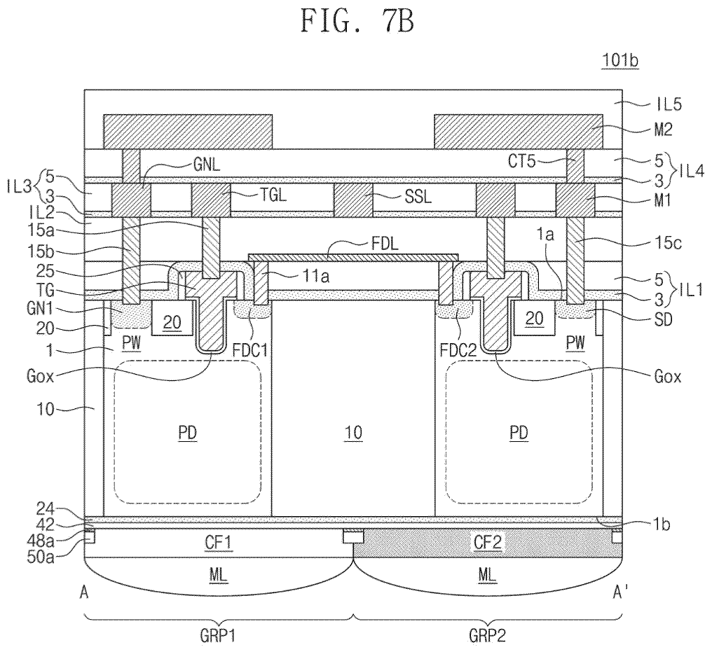

FIG. 7A is a cross-sectional view of an example taken along the line A-A′ of FIG. 2 according to one or more embodiments.

Referring to FIG. 7A, in an image sensor 101a according to one or more embodiments, the second substrate connection contact plug 15c of FIG. 5 may be replaced with a substrate connection contact structure CTS. The substrate connection contact structure CTS may connect the first interconnection line M1 to the source/drain region SD. The substrate connection contact structure CTS may include a first conductive pattern 11e, a second conductive pattern 13e, and a third conductive pattern 15e, which are sequentially stacked. The first conductive pattern 11e may be provided to penetrate the first interlayer insulating layer IL1 and may have the same material and height as the FD connection contact plug 11a. The second conductive pattern 13e may have the same material and thickness as the FD connection line FDL. The third conductive pattern 15e may have the same material and height as the second gate contact plugs 15a. Except for these differences, other portions of the image sensor may be configured to have the same or similar features as those described above.

FIG. 7B is a cross-sectional view of an example taken along the line A-A′ of FIG. 2 according to one or more embodiments.

Referring to FIG. 7B, the first gate contact plugs 11b and the gate conductive pads 13a illustrated in FIGS. 5 and 7A may not be provided in an image sensor 101b according to one or more embodiments. The second gate contact plugs 15a may penetrate the second interlayer insulating layer IL2 and the first interlayer insulating layer IL1 and may contact or be adjacent to the gate electrodes TG, RG, DCG1, DCG2, SF1, SF2, SEL, DM1, and DM2. The third ohmic layer OH3 (e.g., see FIG. 6) may be interposed between the second gate contact plugs 15a and the gate electrodes TG, RG, DCG1, DCG2, SF1, SF2, SEL, DM1, and DM2. Vertical lengths of the second gate contact plugs 15a may be larger than those of the first gate contact plugs 11b. Except for the afore-described differences, the image sensor according to the present embodiment may have substantially the same features as that described with reference to FIGS. 5 and 7A.

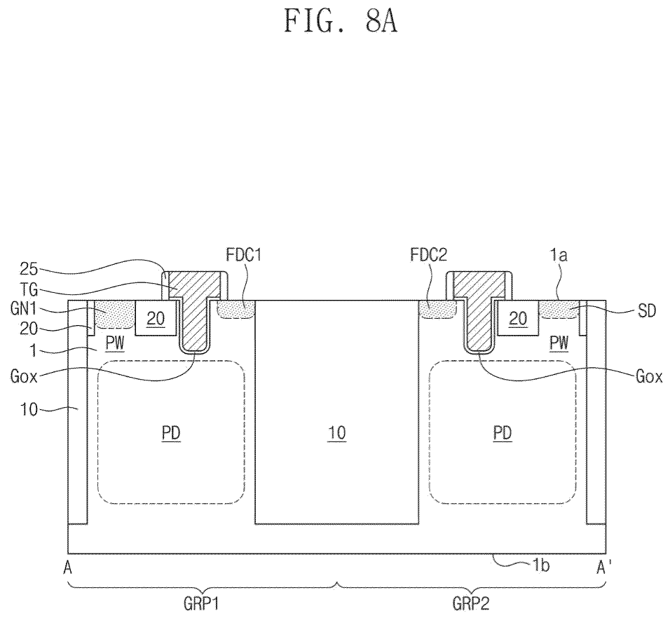

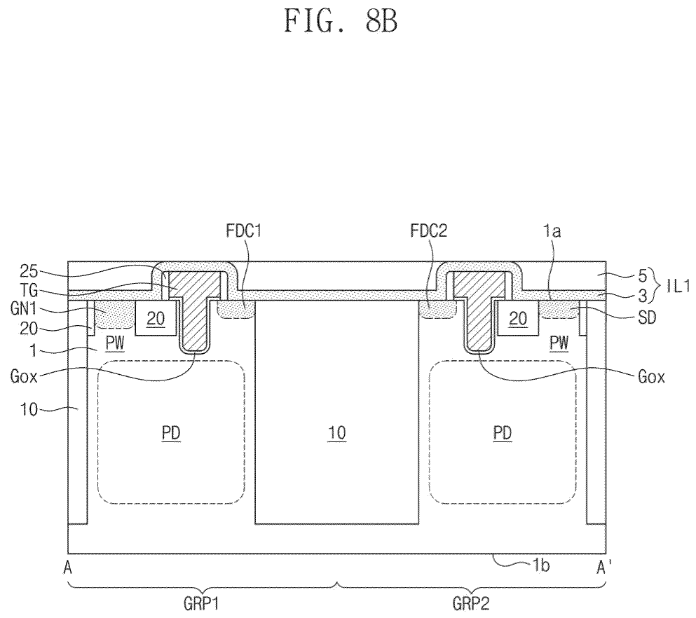

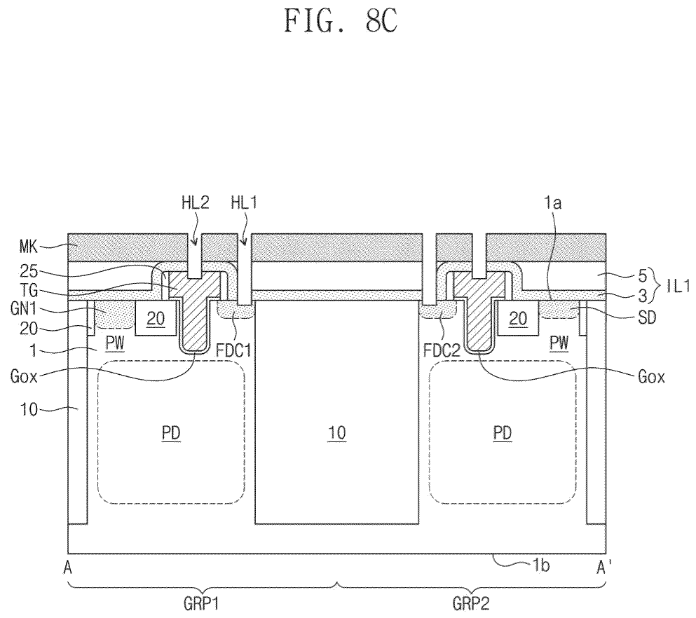

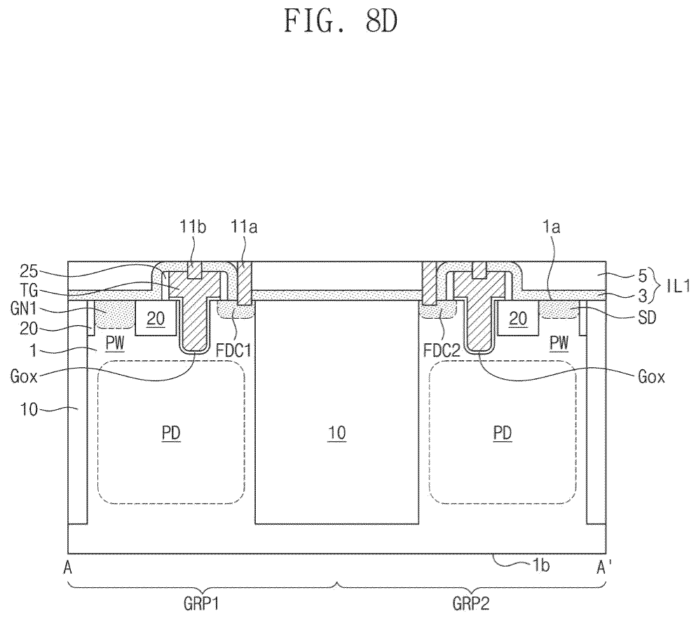

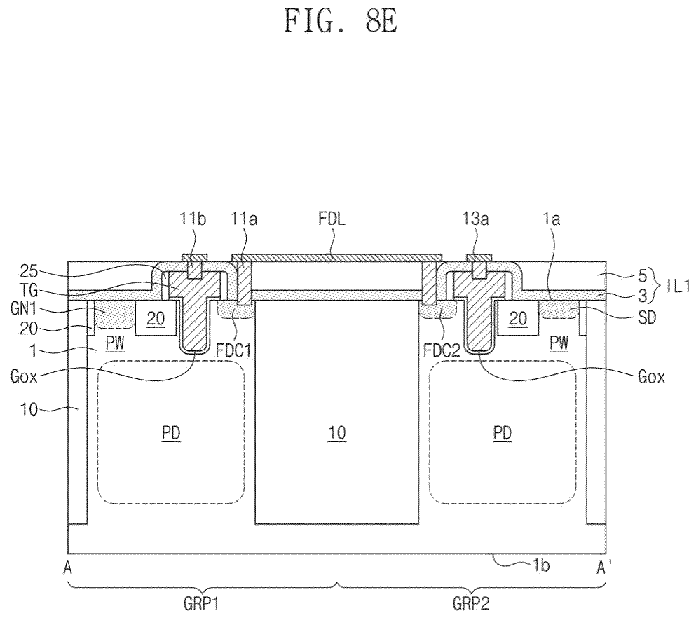

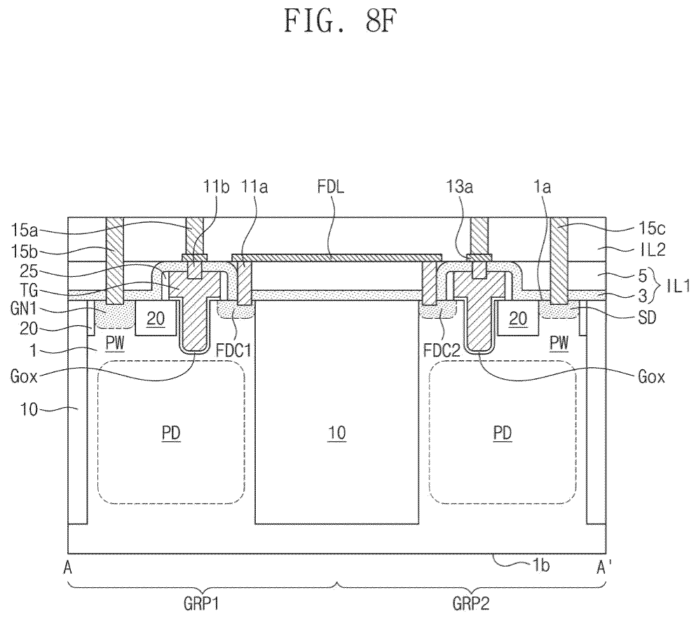

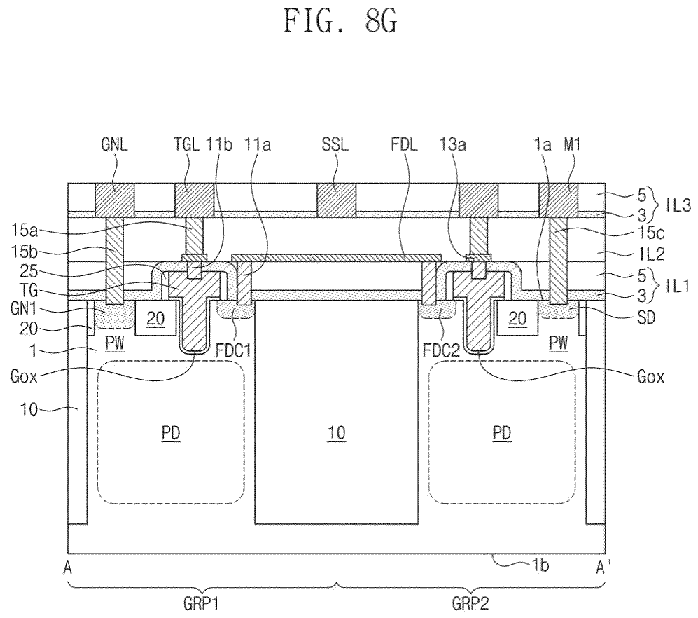

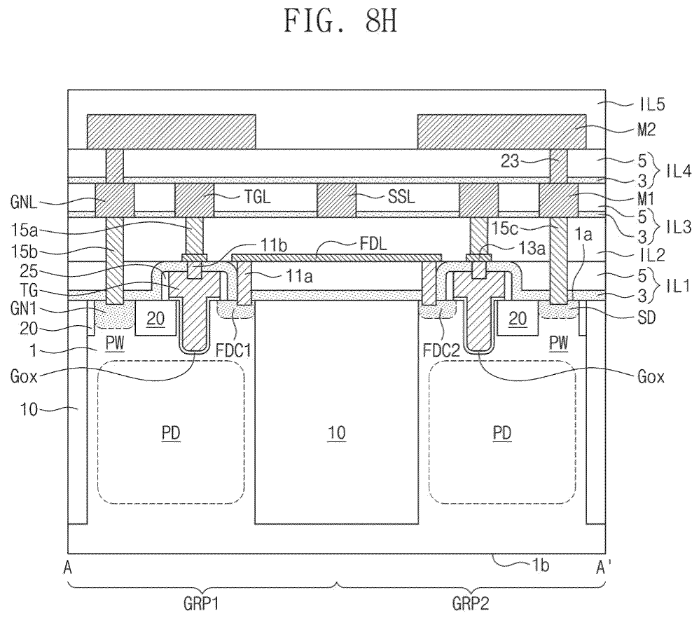

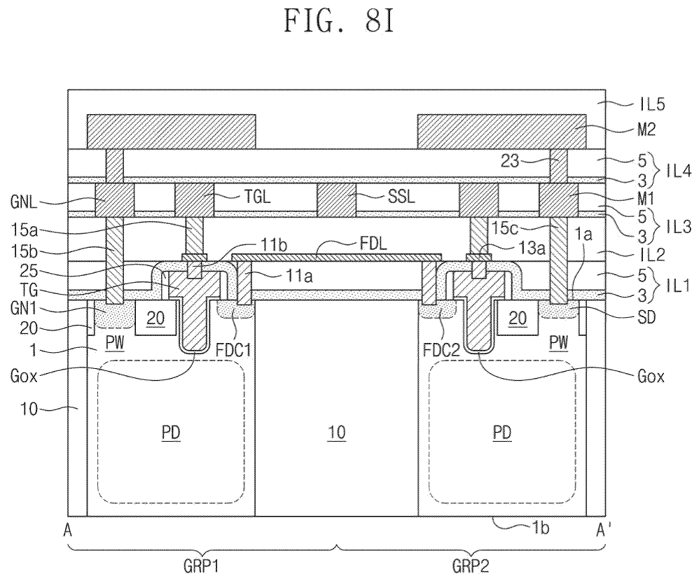

FIGS. 8A to 8I are diagrams illustrating a fabrication process according to one or more embodiments. As an example, FIGS. 8A to 8I are diagrams illustrating a fabrication process of the device shown in FIG. 5, but the operations may be implemented in a fabrication process of similar devices without departing from the scope of the disclosure.

Referring to FIGS. 1 and 8A, the well region PW, the pixel isolation portion 10, the device isolation portion 20, and the photoelectric conversion component PD may be formed in the substrate 1. A bottom surface of the pixel isolation portion 10 may be spaced apart from the second surface 1b of the substrate 1. The gate insulating layer Gox, the transfer gate electrode TG, and the gate electrodes RG, DCG1, DCG2, SF1, SF2, SEL, DM1, and DM2 may be formed on the first surface 1a of the substrate 1. The spacer 25 may be formed to cover a side surface of the transfer gate electrode TG. The floating diffusion regions FD and the first and second common floating diffusion regions FDC1 and FDC2 may be formed in the substrate 1. The ground regions GN1 and GN2 and the source/drain regions SD may be formed in the substrate 1.

Referring to FIGS. 1 and 8B, the etch stop layer 3 may be stacked on the first surface 1a of the substrate 1 and conformally cover the first surface 1a of the substrate 1. The planarization layer 5 may be formed on the etch stop layer 3, and then, a chemical mechanical polishing (CMP) process may be performed to expose a top portion of the etch stop layer 3. In this case, the planarization layer 5 may be formed to fill a space between the transfer gate electrode TG and the gate electrodes RG, DCG1, DCG2, SF1, SF2, SEL, DM1, and DM2 and have a flat top surface. Thus, the first interlayer insulating layer IL1, which may be composed of the etch stop layer 3 and the planarization layer 5, may be formed.

Referring to FIGS. 1 and 8C, a mask pattern MK may be formed on the first interlayer insulating layer IL1. The mask pattern MK may include first holes HL1 and second holes HL2. The mask pattern MK may be formed of or include a material (e.g., at least one of photoresist, spin-on-hardmask (SOH), amorphous carbon layer (ACL), polysilicon, and SiGe) having an etch selectivity with respect to the first interlayer insulating layer IL1. The first hole HL1 may be used to define the position and shape of the FD connection contact plug 11a, and the second hole HL2 may be used to define the position and shape of the first gate contact plug 11b. The positions and shapes of the first and second holes HL1 and HL2 may extend into the first interlayer insulating layer IL1 by etching the first interlayer insulating layer IL1 using the mask pattern MK as an etch mask.

Referring to FIGS. 1, 8C, and 8D, the mask pattern MK may be removed to expose a top surface of the first interlayer insulating layer IL1. A conductive layer may be formed to fill the first and second holes HL1 and HL2 of the first interlayer insulating layer IL1, and then, an etch-back or CMP process may be performed on the conductive layer to form the first contact plugs 11a and 11b in the first and second holes HL1 and HL2.

Referring to FIGS. 1 and 8E, the FD connection line FDL and the gate conductive pads 13a may be formed by depositing a first conductive layer on the first interlayer insulating layer IL1 and etching the first conductive layer.

Referring to FIGS. 2 and 8F, the second interlayer insulating layer IL2 may be stacked on the first interlayer insulating layer IL1. Next, the second contact plugs 15a, 15b, and 15c may be formed to penetrate the second interlayer insulating layer IL2.

Referring to FIGS. 2 and 8G, the third interlayer insulating layer IL3 may be formed on the second interlayer insulating layer IL2. An etching process, a plating process, and a CMP process may be performed to form the ground line GNL, the transfer gate connection line TGL, the SF-SEL connection line SSL, and the first interconnection lines M1 in the third interlayer insulating layer IL3.

Referring to FIG. 8H, the fourth interlayer insulating layer IL4, the third contact plugs 23, the fifth interlayer insulating layer IL5, and the second interconnection lines M2 may be formed on the third interlayer insulating layer IL3.

Referring to FIG. 8I, a back-grinding process may be performed on the second surface 1b of the substrate 1 to remove a portion of the substrate 1 and to expose the pixel isolation portion 10.

Next, referring back to FIG. 5, the fixed charge layer 24, the anti-reflection layer 42, the first grid pattern 48a, the second grid pattern 50a, the color filters CF1 and CF2, and the micro lenses ML may be formed on the second surface 1b of the substrate 1.

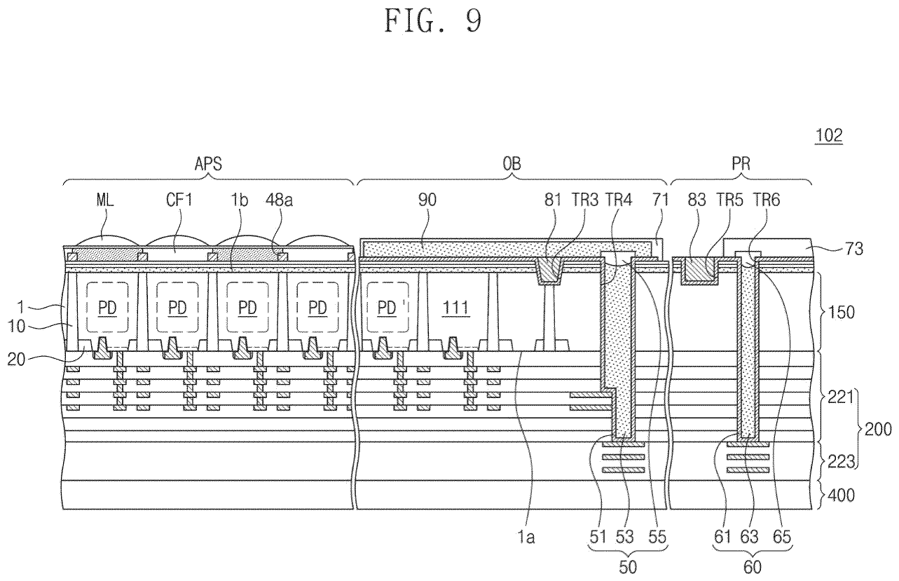

FIG. 9 is a cross-sectional view illustrating an image sensor according to one or more embodiments.

Referring to FIG. 9, an image sensor 102 may include a substrate 1 with a pixel array region APS, an optical black region OB, and a pad region PR, an interconnection layer 200 on the first surface 1a of the substrate 1, and a base substrate 400 on the interconnection layer 200.

The interconnection layer 200 may include an upper interconnection layer 221 and a lower interconnection layer 223. The pixel array region APS may include the pixels PX described with reference to FIGS. 1 to 7B.

In the optical black region OB, a first connection structure 50, a first conductive pad 81, and a bulk color filter 90 may be provided on the substrate 1. The first connection structure 50 may include a first light-blocking pattern 51, an insulating pattern 53, and a first capping pattern 55. The first light-blocking pattern 51 may include a conductive material. For example, the first light-blocking pattern 51 may be formed of or include titanium or tungsten.

The first light-blocking pattern 51 may be provided on the second surface 1b of the substrate 1. The first light-blocking pattern 51 may conformally cover inner surfaces of third and fourth trenches TR3 and TR4. The first light-blocking pattern 51 may be provided to penetrate a photoelectric conversion layer 150 and the upper interconnection layer 221 and to connect the photoelectric conversion layer 150 to the interconnection layer 200.

The first light-blocking pattern 51 may contact an isolation conductive pattern 14 of the pixel isolation portion 10 of FIG. 2A. The first conductive pad 81 may be electrically connected to an isolation conductive pattern of the pixel isolation portion 10. The first light-blocking pattern 51 may block light, which is incident into the optical black region OB.

The first conductive pad 81 may be provided in the third trench TR3 to fill a remaining portion of the third trench TR3. The first conductive pad 81 may be formed of or include at least one of metallic materials (e.g., aluminum). A negative bias voltage may be applied to the isolation conductive pattern 14 through the first conductive pad 81. In this case, a white spot issue or a dark current issue may be prevented or suppressed.

The insulating pattern 53 may fill a remaining portion of the fourth trench TR4. The insulating pattern 53 may be formed to penetrate the photoelectric conversion layer 150 and the entirety or at least a portion of the interconnection layer 200. The first capping pattern 55 may be provided on a top surface of the insulating pattern 53. The first capping pattern 55 may be provided on the insulating pattern 53.

The bulk color filter 90 may be provided on the first conductive pad 81, a first light-blocking pattern 121, and a first capping pattern 125. The bulk color filter 90 may cover the first conductive pad 81, the first light-blocking pattern 51, and the first capping pattern 55. A first protection layer 71 may be provided on the bulk color filter 90 to hermetically seal the bulk color filter 90.

In one or more embodiments, a plurality of pixels PX may also be disposed in the optical black region OB, and a first reference photoelectric conversion component PD′ and a second reference region 111 may be disposed in the pixels PX. The first reference photoelectric conversion component PD′ may be used to obtain a first reference charge amount, which is information about an amount of electric charges generated in a light-blocking state. The first reference charge amount may be used as a reference data for comparison with an amount of charges produced in each of the pixels PX. The second reference region 111 may be used to obtain a second reference charge amount, which is information about an amount of electric charges generated when the photoelectric conversion component PD is absent. The second reference charge amount may be used as information to remove a process noise.

In the pad region PR, a second connection structure 60, a second conductive pad 83, and a second protection layer 73 may be provided on the substrate 1. The second connection structure 60 may include a second light-blocking pattern 61, an insulating pattern 63, and a second capping pattern 65.

The second light-blocking pattern 61 may be provided on the second surface 1b of the substrate 1. The second light-blocking pattern 61 may conformally cover inner surfaces of fifth and sixth trenches TR5 and TR6. The second light-blocking pattern 61 may be provided to penetrate the photoelectric conversion layer 150 and the upper interconnection layer 221 and to connect the photoelectric conversion layer 150 to the interconnection layer 200. The second light-blocking pattern 61 may contact the interconnection lines in the lower interconnection layer 223. The second light-blocking pattern 61 may be electrically connected to the interconnection lines in the interconnection layer 200. The second light-blocking pattern 61 may be formed of or include at least one of metallic materials (e.g., titanium or tungsten).

The second conductive pad 83 may be provided in the fifth trench TR5 to fill a remaining portion of the fifth trench TR5. The second conductive pad 83 may be formed of or include at least one of metallic materials (e.g., aluminum). The second conductive pad 83 may be used as a conduction path for the electric connection to the outside of the image sensor. The insulating pattern 63 may fill a remaining portion of the sixth trench TR6. The insulating pattern 63 may be provided to penetrate the photoelectric conversion layer 150 and the entirety or at least a portion of the interconnection layer 200. The second capping pattern 65 may be provided on the insulating pattern 63. The second protection layer 73 may cover a portion of the second light-blocking pattern 61 and the second capping pattern 65.

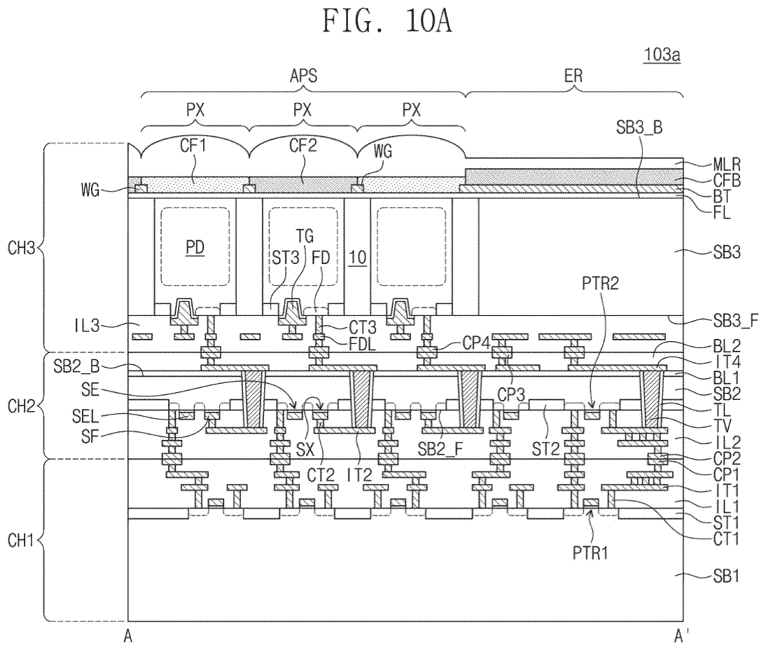

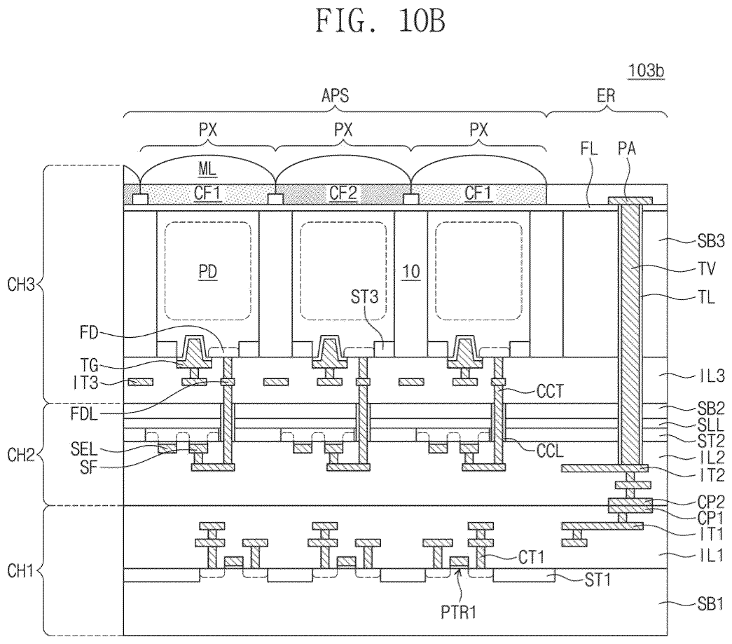

The structure of the image sensor described with reference to FIGS. 1 to 7B may be applied to an image sensor with a 3-chip structure, illustrated in FIGS. 10A and 10B.

FIG. 10A is a cross-sectional view illustrating an image sensor according to one or more embodiments.

Referring to FIG. 10A, an image sensor 103a according to one or more embodiments may have a structure, in which first to third sub-chips CH1 to CH3 may be sequentially stacked. The first sub-chip CH1 may include a first substrate SB1 and a first interlayer insulating layer IL1, which may be provided to cover a front surface of the first substrate SB1. The first substrate SB1 may be a semiconductor substrate or an insulating substrate. The first interlayer insulating layer IL1 may be formed of or include at least one of SiO₂, SiN, SiCN, SiON, and SiOCH, and may have a single-layered or multi-layered structure. Logic circuits may be provided on the first sub-chip CH1. The logic circuits may include a row driver, a row decoder, a column decoder, a timing generator, a correlated double sampler (CDS), and an analog-to-digital converter (ADC). First peripheral transistors PTR1, first contact plugs CT1, and first interconnection lines IT1 may be disposed on the first substrate SB1 to constitute the logic circuits. A first device isolation portion ST1 may be disposed on the first substrate SB1 to delimit active regions for the first peripheral transistors PTR1. First conductive pads CP1 may be disposed in a top portion of the first interlayer insulating layer IL1.

The second sub-chip CH2 may be on and bonded to the first sub-chip CH1. The second sub-chip CH2 may include a second substrate SB2. A front surface SB2_F of the second substrate SB2 may be covered with a second interlayer insulating layer IL2. The second substrate SB2 may be disposed such that the front surface SB2_F faces the first sub-chip CH1. The driving transistors RX, DCX1, DCX2, SX, and SE of FIG. 4 may be disposed in a main region of the second sub-chip CH2 and on the front surface SB2_F of the second substrate SB2. Each of the gate electrodes RG, DCG1, DCG2, SF1, SF2, and SEL may be of a planar type or a vertical type. Each of the driving transistors RX, DCX1, DCX2, S1, S2, and SE may be one of a fin field-effect transistor (FET) (FinFET), a multi-bridge-channel FET (MBCFET™), or a gate-all-around FET (GAAFET).

Second peripheral transistors PTR2 may be disposed in an edge region of the second sub-chip CH2 and on the front surface SB2_F of the second substrate SB2. A second device isolation portion ST2 may be disposed in the second substrate SB2 near the front surface SB2_F to delimit active regions for the driving transistors RX, DCX1, DCX2, SX, and SE and the second peripheral transistors PTR2. Second contact plugs CT2 and second interconnection lines IT2 may be disposed in the second interlayer insulating layer IL2. Second conductive pads CP2 may be disposed in a bottom portion of the second interlayer insulating layer IL2. A bottom surface of the second interlayer insulating layer IL2 may contact the top surface of the first interlayer insulating layer IL1. The second conductive pads CP2 may contact the first conductive pads CP1, respectively. Each pair of the first and second conductive pads CP1 and CP2 may contact each other, without any interface therebetween, and may form a single object.

A rear surface SB2_B of the second substrate SB2 may be sequentially covered with first and second back-side insulating layers BL1 and BL2. Fourth interconnection lines IT4 may be disposed in the second back-side insulating layer BL2. Third bonding pads CP3 may be disposed in a top portion of the second back-side insulating layer BL2. Penetration vias TV may be provided to penetrate the first back-side insulating layer BL1, the second substrate SB2, the second device isolation portion ST2, and a portion of the second interlayer insulating layer IL2 and may contact some of the second interconnection lines IT2, respectively. The penetration vias TV may have a downward decreasing width. A via insulating layer TL may be interposed between the penetration vias TV and the second substrate SB2.

The third sub-chip CH3 may be on and bonded to the second sub-chip CH2. The third sub-chip CH3 may include a third substrate SB3. The third substrate SB3 may include a pixel array region APS and an edge region ER. The pixel array region APS may include a plurality of pixels PX. The pixel isolation portion 10 may be disposed in the third substrate SB3 to separate the pixels PX from each other. In each of the pixels PX, the photoelectric conversion component PD may be disposed in the third substrate SB3. The third substrate SB3 may be disposed to have a front surface SB3_F facing the second sub-chip CH2. A third device isolation portion ST3 may be disposed in the third substrate SB3 near the front surface SB3_F to delimit active regions for the transfer transistors T1 to T8 (e.g., see FIG. 4) and the ground regions GN1 and GN2.

The transfer gates TG and the floating diffusion regions FD may be disposed on and in the front surface SB3_F of the third substrate SB3. The front surface SB3_F of the third substrate SB3 may be covered with the third interlayer insulating layer IL3. Third contact plugs CT3, FD connection interconnection lines FDL, and third interconnection lines IT3 may be disposed in the third interlayer insulating layer IL3. Each of the FD connection interconnection lines FDL may connect at least two of the floating diffusion regions FD of the pixels PX, which are adjacent to each other, to each other. The floating diffusion regions FD of the third sub-chip CH3 may be connected to the source follower gate electrodes SF of the source follower transistors SX of the second sub-chip CH2.

A bottom surface of the third interlayer insulating layer IL3 may contact a top surface of the second back-side insulating layer BL2 of the second sub-chip CH2. Fourth conductive pads CP4 may be disposed in a bottom portion of the third interlayer insulating layer IL3. The fourth conductive pads CP4 may contact the third conductive pads CP3, respectively. Each pair of the third and fourth conductive pads CP3 and CP4 may contact each other, without any interface therebetween, and may form a single object.

A rear surface SB3_B of the third substrate SB3 may be covered with a third back-side insulating layer FL. The third back-side insulating layer FL may include at least one of a fixed charge layer, an anti-reflection layer, a planarization layer, or a protection layer. In the pixel array region APS, a grid pattern WG, color filters CF1 and CF2, and micro lenses ML may be disposed on the fixed charge layer FL. In the edge region ER, a first optical black pattern BT, a second optical black pattern CFB, and a lens residue layer MLR may be sequentially disposed on the fixed charge layer FL. The first optical black pattern BT may be formed to have the same material and thickness as the grid pattern WG. The second optical black pattern CFB may be composed of a blue color filter. The lens residue layer MLR may be formed of or include the same material as the micro lenses ML. Except for these differences, other portions of the image sensor may be configured to have the same or similar features as the previous embodiments.

FIG. 10B is a cross-sectional view illustrating an image sensor according to one or more embodiments.

Referring to FIG. 10B, an image sensor 103b according to one or more embodiments may have a structure, in which the first to third sub-chips CH1 to CH3 may be sequentially stacked. The first sub-chip CH1 may be provided to have the same or similar features as those described above in FIG. 10A, and repeated descriptions may be omitted. The second and third sub-chips CH2 and CH3 may also be provided to have the same or similar features as those described above in FIG. 10A, and repeated descriptions may be omitted. The second substrate SB2 may be a semiconductor substrate, an insulating substrate, or an SOI substrate. The first conductive pads CP1 may be disposed in a top portion of the first sub-chip CH1. Furthermore, generally, the image sensor 103b may have substantially the same features as that described with reference to FIG. 10A, and repeated descriptions may be omitted.

A substrate insulating layer SLL may be disposed in the second substrate SB2 of the second sub-chip CH2. Penetration contact plugs CCT may be provided to penetrate the second substrate SB2, a portion of the second interlayer insulating layer IL2, and a portion of the third interlayer insulating layer IL3 and may connect the FD connection interconnection lines FDL to the source follower gate electrodes SF. A penetration contact insulating layer CCL may be interposed between the penetration contact plug CCT and the second substrate SB2. The second conductive pads CP2 may be disposed in a bottom portion of the second sub-chip CH2. The second conductive pads CP2 may contact the first conductive pads CP1, respectively.

An input/output pad PA may be disposed in the edge region ER of the third sub-chip CH3 and on the third back-side insulating layer FL. The penetration via TV may be provided to penetrate the third substrate SB3 and the third interlayer insulating layer IL3 of the third sub-chip CH3 and the second substrate SB2 and a portion of the second interlayer insulating layer IL2 of the second sub-chip CH2 and may connect the input/output pad PA to the second interconnection lines IT2.

The positions of the conductive pads CP1-CP4 and the penetration via TV may not be limited to those described with respect to FIGS. 10A and 10B and may be variously changed. The positions of the transfer transistors T1-T8 and the driving transistors RX, DCX1, DCX2, S1, S2, and SE may not be limited to those described with respect to FIGS. 10A and 10B and may be variously changed. A precharge transistor, a sampling transistor, and/or a capacitor may be disposed in at least one of the first and second sub-chips CH1 and CH2.

In an image sensor according to one or more embodiments, a first interconnection line connecting floating diffusion regions may be located at a different level from a second interconnection line connected to a ground region, and thus, a parasitic capacitance therebetween may be reduced, to increase a conversion gain, and to reduce a noise. As a result, the image sensor may be fabricated to realize a high-quality image.

Furthermore, since the interconnection lines are located at different levels, the second interconnection line may be placed, without considering a planar position of the first interconnection line connecting the floating diffusion regions. That is, a degree of freedom in placing the second interconnection line may be increased. In addition, a contact plug in contact with the floating diffusion region may be formed of polysilicon, and thus, a junction leakage may be reduced.

Each of the embodiments provided in the above description is not excluded from being associated with one or more features of another example or another embodiment also provided herein or not provided herein but consistent with the disclosure.

While the disclosure has been particularly shown and described with reference to embodiments thereof. it will be understood that various changes in form and details may be made therein without departing from the spirit and scope of the following claims.

What is claimed is:

1. An image sensor, comprising:
a substrate;
a first floating diffusion region and a second floating diffusion region in the substrate and spaced apart from each other;
a ground region in the substrate and spaced apart from the first floating diffusion region and the second floating diffusion region;
a first interconnection line on the substrate and connecting the first floating diffusion region and the second floating diffusion region;
a second interconnection line on the substrate and connected to the ground region,
wherein the first interconnection line is at a first level, and
wherein the second interconnection line is at a second level that is different from the first level.

2. The image sensor of claim 1, further comprising:
a first interlayer insulating layer at least partially covering the substrate and contacting a bottom surface of the first interconnection line; and
a second interlayer insulating layer at least partially covering the first interconnection line and the first interlayer insulating layer, the second interlayer insulating layer contacting a bottom surface of the second interconnection line,
wherein an electrical resistivity of the first interconnection line is greater than an electrical resistivity of the second interconnection line.

3. The image sensor of claim 2, wherein the first interconnection line has a first thickness, and
wherein the second interconnection line has a second thickness that is greater than the first thickness.

4. The image sensor of claim 2, further comprising:
a first contact plug penetrating the first interlayer insulating layer and connecting the first interconnection line to the first floating diffusion region; and
a second contact plug penetrating the first interlayer insulating layer and the second interlayer insulating layer, and connecting the second interconnection line to the ground region,
wherein the first contact plug comprises polysilicon doped with impurities of a first conductivity type, and
wherein the second contact plug comprises a metallic materials.

5. The image sensor of claim 4, further comprising a source follower gate electrode on the substrate and spaced apart from the first floating diffusion region and the second floating diffusion region,
wherein a portion the first interconnection line overlaps a portion of the source follower gate electrode.

6. The image sensor of claim 5, further comprising a third contact plug connecting the first interconnection line to the source follower gate electrode.

7. The image sensor of claim 4, wherein the first floating diffusion region and the second floating diffusion region are doped with impurities of the first conductivity type.

8. The image sensor of claim 4, further comprising:
a first ohmic layer between the first interconnection line and the first contact plug; and
a second ohmic layer between the second contact plug and the ground region.

9. The image sensor of claim 2, further comprising:
a first transfer gate electrode on the substrate and adjacent to the first floating diffusion region;
a first etch stop layer between the first interlayer insulating layer and the first transfer gate electrode;
a third contact plug penetrating the first etch stop layer and contacting the first transfer gate electrode; and
a conductive pad on the third contact plug,
wherein a thickness of the conductive pad is substantially the same as a thickness of the first interconnection line.

10. The image sensor of claim 2, further comprising:
a first transfer gate electrode and a second transfer gate electrode, the first transfer gate electrode and the second transfer gate electrode being adjacent to the first floating diffusion region in a first direction, are spaced apart from each other in a second direction intersecting the first direction, and at least partially covered by the first interlayer insulating layer and the second interlayer insulating layer; and
a third interconnection line on the second interlayer insulating layer and connecting the first transfer gate electrode to the second transfer gate electrode,
wherein the first interconnection line has a first thickness, and
wherein the second interconnection line and the third interconnection line have a second thickness that is greater than the first thickness.

11. The image sensor of claim 10, further comprising:
a first contact plug penetrating the second interlayer insulating layer and connected to the first transfer gate electrode;
a second contact plug penetrating the second interlayer insulating layer and connected to the second transfer gate electrode;
a first conductive pad between the first contact plug and the first transfer gate electrode; and
a second conductive pad between the second contact plug and the second transfer gate electrode,
wherein the first conductive pad and the second conductive pad have the first thickness.

12. The image sensor of claim 1, wherein the substrate comprises a first pixel group and a second pixel group adjacent to each other in a first direction, the first pixel group and the second pixel group comprising pixels arranged in a 2×2 matrix,
wherein the first floating diffusion region is at a center of the first pixel group,
wherein the second floating diffusion region is at a center of the second pixel group,
wherein the first pixel group comprises a first pixel that is adjacent to the second pixel group,
wherein the second pixel group comprises a second pixel that is adjacent to the first pixel in the first direction,
wherein the image sensor further comprises:
a pixel isolation portion between the first pixel and the second pixel; and
a source follower gate electrode at least partially covering the first pixel, the second pixel, and the pixel isolation portion.

13. An image sensor, comprising:
a first floating diffusion region;
a ground region spaced apart from the first floating diffusion region;
a source follower gate electrode spaced apart from the first floating diffusion region;
a first interlayer insulating layer on the source follower gate electrode;
a first interconnection line on the first interlayer insulating layer and connecting the first floating diffusion region to the source follower gate electrode;
a second interlayer insulating layer on the first interconnection line and the first interlayer insulating layer; and
a second interconnection line on the second interlayer insulating layer and connected to the ground region,
wherein the first interconnection line has a first thickness, and
wherein the second interconnection line has a second thickness that is larger than the first thickness.

14. The image sensor of claim 13, wherein an electrical resistivity of the first interconnection line is greater than an electrical resistivity of the second interconnection line.

15. The image sensor of claim 13, further comprising:
a first contact plug penetrating the first interlayer insulating layer and connecting the first interconnection line to the first floating diffusion region; and
a second contact plug penetrating the first interlayer insulating layer and the second interlayer insulating layer, the second contact plug connecting the second interconnection line to the ground region,
wherein the first contact plug comprises polysilicon doped with impurities of a first conductivity type, and
wherein the second contact plug comprises a metallic material.

16. An image sensor, comprising:
a substrate comprising a pixel array region, an optical black region, and a pad region, the pixel array region comprising a first pixel group and a second pixel group adjacent to each other in a first direction, the first pixel group and the second pixel group comprising pixels that are arranged in a 2×2 matrix;
a pixel isolation portion in the substrate and separating the first pixel group and the second pixel group;
a first floating diffusion region at a center of the first pixel group;
a second floating diffusion region at a center of the second pixel group;
a ground region in the substrate and in one of the pixels of the first pixel group;
a first transfer gate electrode adjacent to the first floating diffusion region;
a second transfer gate electrode adjacent to the second floating diffusion region;
a first interlayer insulating layer at least partially covering the substrate, the first floating diffusion region, the second floating diffusion region, the ground region, the first transfer gate electrode and the second transfer gate electrode;
a first interconnection line on the first interlayer insulating layer and connecting the first floating diffusion region to the second floating diffusion region;
a second interlayer insulating layer at least partially covering the first interconnection line and the first interlayer insulating layer;
a second interconnection line on the second interlayer insulating layer and connected to the ground region;
a light-blocking pattern on the second interlayer insulating layer and in the optical black region;
a conductive pad on the second interlayer insulating layer and in the pad region;
a first contact plug penetrating the first interlayer insulating layer and connecting the first interconnection line to the first floating diffusion region; and
a second contact plug penetrating the first interlayer insulating layer and the second interlayer insulating layer, the second contact plug connecting the second interconnection line to the ground region,
wherein the first contact plug comprises polysilicon doped with impurities of a first conductivity type, and
wherein the second contact plug comprises a metallic material.

17. The image sensor of claim 16, wherein the first pixel group comprises a first pixel adjacent to the second pixel group,
wherein the second pixel group comprises a second pixel that is adjacent to the first pixel in the first direction,
wherein the pixel isolation portion is between the first pixel and the second pixel,
wherein the image sensor further comprises a source follower gate electrode at least partially covering the first pixel, the second pixel, and the pixel isolation portion, and
wherein a portion of the first interconnection line overlaps with a portion of the source follower gate electrode.

18. The image sensor of claim 17, further comprising a third contact plug penetrating the first interlayer insulating layer and connecting the first interconnection line to the source follower gate electrode,
wherein the third contact plug comprises polysilicon doped with impurities of the first conductivity type.

19. The image sensor of claim 16, wherein an electrical resistivity of the first interconnection line is greater than an electrical resistivity of the second interconnection line.

20. The image sensor of claim 16, wherein the first interconnection line has a first thickness, and
wherein the second interconnection line has a second thickness larger than the first thickness.
